(19) United States
(12) Patent Application Publication
(10) Pub. No.: US 2019/0088201 A1
(43) Pub. Date: Mar. 21, 2019

(54) DISPLAY APPARATUS AND DRIVING METHOD THEREOF

(71) Applicants: HKC Corporation Limited, Shenzhen City, Guangdong (CN); Chongqing HKC Optoelectronics Technology Co., Ltd., Chongqing (CN)

(72) Inventors: Wenqin ZHAO, Chongqing (CN); Wei CHEN, Chongqing (CN)

(21) Appl. No.: 15/580,435

(22) PCT Filed: Oct. 20, 2017
(86) PCT No.: PCT/CN2017/107032

§ 371 Date: Dec. 7, 2017

(30) Foreign Application Priority Data
Sep. 15, 2017 (CN) 201710833207.0

(51) Int. Cl. G09G 3/3258; H01L 27/32

(52) U.S. Cl. CPC G09G 3/3258; G09G 2310/08; G09G 2310/0264; H01L 27/3213

(57) ABSTRACT

This application provides a display apparatus and a driving method thereof. The display apparatus includes: a voltage regulation unit, including a first output line and a first input line, where the first output line outputs a standard voltage, and the first input line inputs a standard feedback voltage; and a display panel, including a second input line and a second output line, where the second input line receives the standard voltage, and the second output line outputs the standard feedback voltage, where: the voltage regulation unit receives the standard feedback voltage, calculates a regulation parameter according to a value of the standard feedback voltage, and regulates the standard voltage according to the regulation parameter.

### BACKGROUND

### Technical Field

This application relates to the field of display technologies, and in particular, to a display apparatus and a driving method thereof.

### Related Art

In a display, a system main board is connected to a Control Board (C-Board) through a line, the C-Board is connected to a printed circuit board (PCB) through, for example, a Flexible Flat Cable (FFC), and the PCB is further connected to a display region through a Source-Chip on Film (S-COF) and a Gate-Chip on Film (G-COF). A driving method of a display includes: transmitting, by a system main board, a color (for example: R/G/B) compressed signal, a control signal, and power to a C-Board. After being processed by a Timing Controller (TCON) on the C-Board, the signals are transmitted to a source circuit and a gate circuit of the PCB, and data and power in need are transmitted to a display region through the S-COF and the G-COF, so that the display receives the power and signals required for presenting a screen.

However, display operation of a display is driven by a voltage. In a display process, the display needs to first generate a standard voltage VCOM. A standard voltage VCOM and a gamma reference voltage Gamma for a display purpose have a direct value correspondence in terms of voltage values of a highest voltage and a lowest voltage. In the related art, a reference voltage generation unit of a PCB generates a reference voltage VREF, the reference voltage VREF and a ground voltage GND are transmitted to a voltage regulation unit such as a Digital Voltage Regulator (DVR) or a mechanical Voltage Regulator (VR). According to a voltage division principle, the voltage regulation unit can perform regulation to receive a required standard voltage VCOM and output the standard voltage VCOM to a display panel.

However, when a value relationship between the standard voltage VCOM and the gamma reference voltage Gamma for a display purpose are asymmetric, a flicker phenomenon may occur. There are usually two solutions to this problem:

(1) When being produced, panels are sampled, an optimal standard voltage VCOM_Y of sample panels is received by commissioning, and further, an optimal standard voltage VCOM of other display panels is considered to be the same as the optimal standard voltage VCOM_Y of the samples. A disadvantage of this solution is: because of unstable processing of display panels in a manufacturing process, there is a processing difference between different display panels, resulting in a difference between optimal standard voltages VCOM of different panels, and consequently, display panels having a difference therebetween have different optimal standard voltages VCOM, and the optimal standard voltages VCOM may not necessarily be the optimal standard voltage VCOM_Y, that is, a flicker phenomenon occurs.

(2) An optical sensor is added to a production line to detect flicker strength, and an optimal standard voltage VCOM of each display panel is commissioned by means of software, and when a flicker phenomenon is the least, an optimal standard voltage VCOM_Y of a display panel is considered to be received. Disadvantages of this solution are: relatively long working hours and inapplicability to products with separate PCBs (X board) and C-Boards (C board). Because the products with separate PCBs (X board) and C-Boards (C board) are usually partially delivered, when the products arrive at a client, an error in an optimal VCOM of a panel may still be caused.

Further, as a service time is extended, a working voltage of a relevant component is attenuated. In addition, because attenuation speeds of voltage signals of types, such as a standard VCOM and a gamma reference voltage Gamma, are inconsistent, after a display panel is used for a long time, the standard voltage VCOM deviates from an optimal voltage value. Therefore, value relationships between various voltages received by the display panel have deviations, further resulting in a degradation problem such as flickers.

### SUMMARY

To resolve the foregoing technical problems, an objective of this application is to provide a display apparatus and a driving method thereof, for alleviating problems, such as flickers, in presentation of a display apparatus by regulating a standard voltage.

The objective of this application is achieved and the technical problem of this application is resolved by using the following technical solutions. A display apparatus is provided according this application, comprising: a voltage regulation unit, comprising a first output line and a first input line, where the first output line outputs a standard voltage, and the first input line inputs a standard feedback voltage; and a display panel, comprising a second input line and a second output line, where the second input line receives the standard voltage, and the second output line outputs the standard feedback voltage, where the voltage regulation unit receives the standard feedback voltage, calculates a regulation parameter according to a value of the standard feedback voltage, and regulates the standard voltage according to the regulation parameter.

The technical problem of this application may be further resolved by taking the following technical measures.

In an embodiment of this application, the voltage regulation unit stores a voltage threshold, the regulation parameter is a deviation value between the standard feedback voltage and the standard voltage, and when the deviation value exceeds the voltage threshold, the voltage regulation unit regulates the standard voltage.

In an embodiment of this application, during a period of regulating, by the voltage regulation unit, the standard voltage, when the deviation value is less than the voltage threshold, the voltage regulation unit stops regulating the standard voltage.

In an embodiment of this application, the voltage regulation unit receives a minimum deviation value out of all the deviation values, and when the minimum deviation value is less than the voltage threshold, the voltage regulation unit stops regulating the standard voltage.

In an embodiment of this application, the voltage regulation unit is configured to continuously receive n standard feedback voltages within a time interval and to take one of the n standard feedback voltages to calculate the deviation value and n is a positive integer.

In an embodiment of this application, the voltage regulation unit takes a maximum one out of the n standard feedback voltages to calculate the deviation value.

In an embodiment of this application, the voltage regulation unit takes a minimum one out of the n standard feedback voltages to calculate the deviation value.

In an embodiment of this application, when the voltage regulation unit regulates the standard voltage, the voltage regulation unit uses the standard voltage as a start and positively or negatively regulates a voltage value range.

A secondary objective of this application is providing a driving method of a display apparatus, comprising: continuously receiving, by using a voltage regulation unit, standard feedback voltages provided by a display panel; calculating, by the voltage regulation unit, a deviation value according to the standard feedback voltages and the standard voltages; and when the deviation value exceeds a voltage threshold, regulating, by the voltage regulation unit, the standard voltage until the voltage regulation unit receives a minimum deviation value from all the deviation values, and the minimum deviation value is less than the voltage threshold.

In an embodiment of this application, the voltage regulation unit stores the voltage threshold.

In an embodiment of this application, the voltage regulation unit is configured to continuously receive n standard feedback voltages within a time interval and to take one of the n standard feedback voltages to calculate the deviation value and n is a positive integer.

In an embodiment of this application, the voltage regulation unit takes a maximum one out of the n standard feedback voltages to calculate the deviation value.

In an embodiment of this application, the voltage regulation unit takes a minimum one out of the n standard feedback voltages to calculate the deviation value.

In an embodiment of this application, the voltage regulation unit includes a comparison unit and the comparison unit performs a calculation on the deviation values and a value comparison between the deviation values and the voltage threshold.

In an embodiment of this application, when the voltage regulation unit regulates the standard voltage, the voltage regulation unit uses the standard voltage as a start and positively regulates a voltage value range.

In an embodiment of this application, when the voltage regulation unit regulates the standard voltage, the voltage regulation unit uses the standard voltage as a start and negatively regulates a voltage value range.

Another objective of this application is a display apparatus, comprising: a voltage regulation unit, comprising a first output line and a first input line, wherein the first output line outputs a standard voltage, the first input line inputs a standard feedback voltage, and the voltage regulation unit stores a voltage threshold; and a display panel, comprising a second input line and a second output line, wherein the second input line receives the standard voltage, and the second output line outputs the standard feedback voltage, where: the voltage regulation unit is configured to continuously receive the standard feedback voltages and to calculate a deviation value according to the standard feedback voltages and the standard voltages; when the deviation value exceeds the voltage threshold, the voltage regulation unit uses the standard voltage as a start and positively or negatively regulates a voltage value range; during a period of regulating, by the voltage regulation unit, the standard voltage, the voltage regulation unit continuously receives the deviation values; the voltage regulation unit receives a minimum deviation value out of all the deviation values, and when the minimum deviation value is less than the voltage threshold, the voltage regulation unit stops regulating the standard voltage.

This application can maintain original processing requirements and product costs on the premise of not greatly changing an existing production process, and after a display apparatus is used for a long time, a standard voltage VCOM can still be maintained at a proper voltage value, and be maintained in a proper value correspondence with a gamma reference voltage, thereby resolving problems of flickers and unstable brightness of the display apparatus caused by deviation of the standard voltage from an optimal value. In addition, when being driven, the display apparatus can perform adaptive regulation on the standard voltage. Therefore, this application is applicable to various display apparatus and is applicable to display and electronic product components delivered partially.

### BRIEF DESCRIPTION OF THE DRAWINGS

FIG. 1a is a schematic structural diagram of configuration of an exemplary display apparatus;

FIG. 1b is a schematic diagram of a local structure of a driving circuit of an exemplary display apparatus;

FIG. 2 is a schematic architectural diagram of a driving circuit for applying an embodiment to a display apparatus according to a method of this application;

FIG. 3 is a schematic architectural diagram of a driving circuit for applying an embodiment to a display apparatus according to a method of this application;

FIG. 4 is a schematic architectural diagram of a driving circuit for applying an embodiment to a display apparatus according to a method of this application; and

FIG. 5 is a schematic diagram of a driving process for applying an embodiment to a display apparatus according to a method of this application.

### DETAILED DESCRIPTION

The following embodiments are described with reference to the accompanying drawings, and are used to exemplify particular embodiments for implementation of this application. Terms about directions mentioned in this application, such as “on”, “below”, “front”, “back”, “left”, “right”, “in”, “out”, and “side face”, merely refer to directions in the accompanying drawings. Therefore, the used terms about directions are used to describe and understand this application, and are not intended to limit this application.

The accompanying drawings and the description are considered to be essentially exemplary, rather than limitative. In the figures, units with similar structures are represented by using the same reference number. In addition, for understanding and ease of description, the size and the thickness of each component shown in the accompanying drawings are arbitrarily shown, but this application is not limited thereto.

In the accompanying drawings, for clarity, thicknesses of a layer, a film, a panel, an area, and the like are enlarged. In the accompanying drawings, for understanding and ease of description, thicknesses of some layers and areas are enlarged. It should be understood that when a component such as a layer, a film, an area, or a base is described to be “on” “another component”, the component may be directly on the another component, or there may be an intermediate component.

In addition, throughout this specification, unless otherwise explicitly described to have an opposite meaning, the word “include” is understood as including the component, but not excluding any other component. In addition, throughout this specification, “on” means that one is located above or below a target component and does not necessarily mean that one is located on the top based on a gravity direction.

To further describe the technical measures taken in this application to achieve the predetermined application objective and effects thereof, specific implementations, structures, features, and effects of a display apparatus and a driving method thereof provided according to this application are described below in detail with reference to the accompanying drawings and preferred embodiments.

A display panel of this application may include a first substrate and a second substrate, and the first substrate and the second substrate may, for example, be a Thin Film Transistor (TFT) substrate and a Color Filter (CF) substrate. However, this application is not limited thereto. In some embodiments, alternatively, an active switch array and a CF in this application may be formed on a same substrate.

In some embodiments, the display panel of this application may, for example, be a liquid crystal display panel. However, this application is not limited thereto. Alternatively, the display panel may be an OLED display panel, a W-OLED display panel, a QLED display panel, a plasma display panel, a curved-surface display panel, or a display panel of another type.

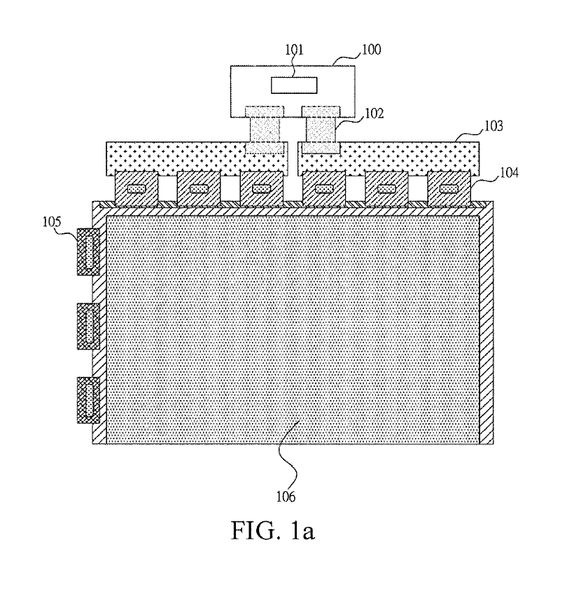

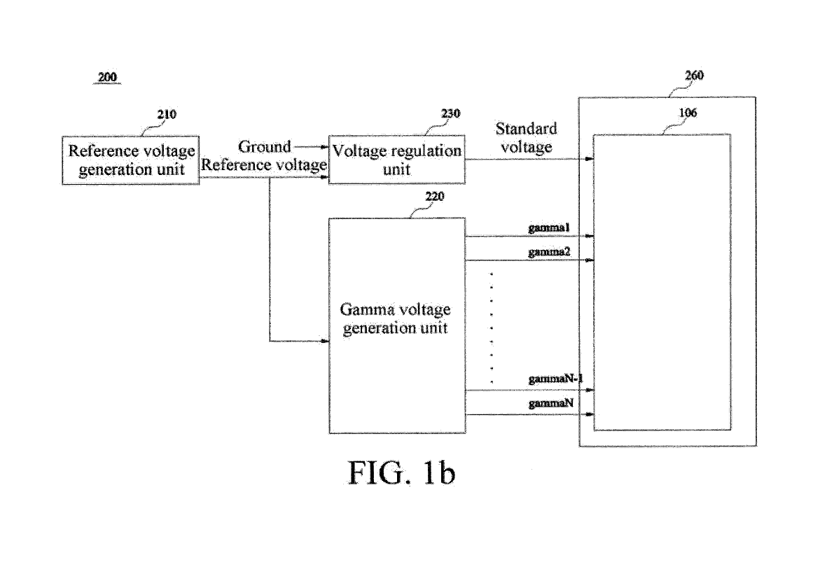

FIG. 1a is a schematic structural diagram of configuration of an exemplary display apparatus, and FIG. 1b is a schematic diagram of a local structure of a driving circuit of an exemplary display apparatus. As shown in FIG. 1a, a driving method of a display apparatus 200 includes: providing and transmitting, by a system main board, a color (for example: R/G/B) compressed signal, a control signal, and power to a C-Board 100. After being processed by a TCON 101 on the C-Board 100, the signals, together with the power processed by the driving circuit, are transmitted to a source circuit and a gate circuit of a PCB 103 through, for example, an FFC 102, and data and power in need are transmitted to a display region 106 through a S-COF 104 and a G-COF 105, so that a display receives the power and signals required for presenting a screen.

As shown in FIG. 1b, the display apparatus 200 includes: a reference voltage generation unit 210, a gamma voltage generation unit 220, and a voltage regulation unit 230. The reference voltage generation unit 210 provides a reference voltage Vref to the gamma voltage generation unit 220, and after the reference voltage Vref is converted by the gamma voltage generation unit 220, a plurality of gamma reference voltages gamma1, gamma2, . . . gammaN−1, and gammaN is output (N is usually 18 or 14). The plurality of gamma reference voltages is separately provided to a display region 106 of a display panel 260, so as to drive each pixel circuit of the display panel 260 using different gray level voltages.

In a display process, the display apparatus 200 needs to first generate a standard voltage VCOM. Generally, a standard voltage VCOM and a gamma reference voltage for a display purpose have a direct value correspondence in teams of voltage values of a highest voltage (such as the foregoing gamma1) and a lowest voltage (such as the foregoing gammaN). In the related art, the reference voltage generation unit 210 generates a reference voltage VREF, the reference voltage VREF and a ground voltage GND are transmitted to the voltage regulation unit 230 such as a DVR or a mechanical VR. According to a voltage division principle, the voltage regulation unit 230 can perform regulation to receive a required standard voltage VCOM and output the standard voltage VCOM to the display panel 106 of the display panel.

However, when a value relationship between the standard voltage VCOM and the gamma reference voltage Gamma for a display purpose are asymmetric, a flicker phenomenon may occur. In addition, because attenuation speeds of the standard voltage VCOM, the reference voltage VREF, and the gamma reference voltage (gamma) are inconsistent, after the display panel is used for a long time, the standard voltage VCOM gradually deviates from an optimal voltage value.

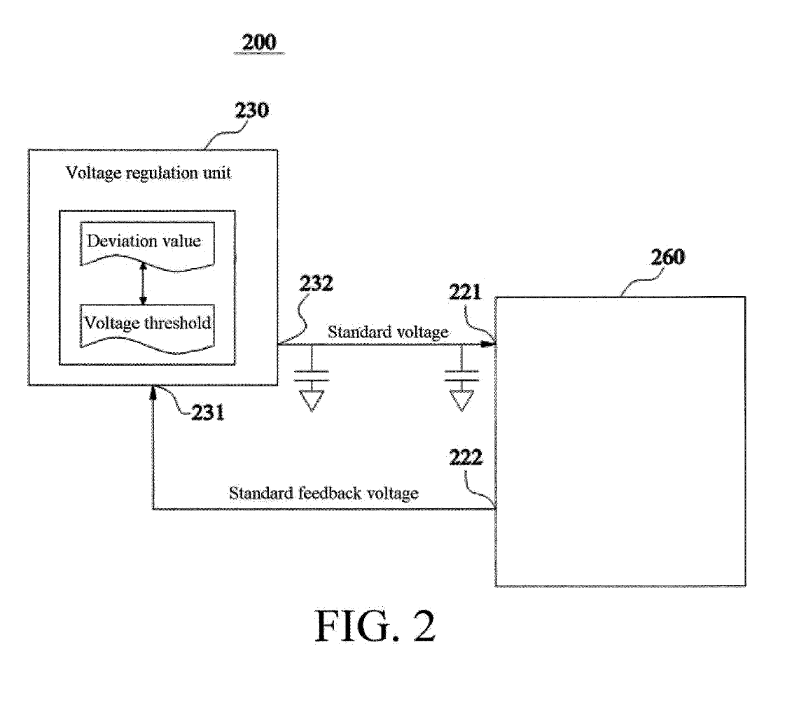

FIG. 2 is a schematic architectural diagram of a driving circuit for applying an embodiment to a display apparatus according to a method of this application. In an embodiment of this application, a display apparatus 200 includes: a voltage regulation unit 230, including a first output line 232 and a first input line 231, where the first output line 232 outputs a standard voltage VCOM, and the first input line 231 inputs a standard feedback voltage VCOM_R; and a display panel 260, including a second input line 221 and a second output line 222, where the second input line 221 receives the standard voltage VCOM, and the second output line 222 outputs the standard feedback voltage VCOM_R, where: the voltage regulation unit 230 receives the standard feedback voltage VCOM_R and calculates a regulation parameter according to a value of the standard feedback voltage VCOM_R so as to regulate the standard voltage VCOM according to the regulation parameter.

In embodiments of this application, the voltage regulation unit 230 stores a voltage threshold Vth, the regulation parameter is a deviation value |VCOM_R−VCOM| between the standard feedback voltage VCOM_R and the standard voltage VCOM, and when the deviation value exceeds the voltage threshold Vth, the voltage regulation unit 230 regulates the standard voltage VCOM.

In some embodiments of this application, the voltage regulation unit 230 includes a comparison unit 235 and the comparison unit performs a calculation on the deviation value |VCOM_R−VCOM| and a value comparison between the deviation value and the voltage threshold Vth.

In some embodiments of this application, the voltage threshold Vth is preset in an execution parameter or a program of the voltage regulation unit 230 or in an execution parameter or a program of the comparison unit 235 or is stored in a storage unit (not shown in the figure) of the display panel 260 for being read and used by the voltage regulation unit 230.

In some embodiments of this application, the voltage regulation unit 230 is configured to continuously receive n standard feedback voltages VCOM_R within a time interval and to take one of the n standard feedback voltages to calculate the deviation value and n is a positive integer.

In some embodiments of this application, the time interval is preset in an execution parameter or a program of the voltage regulation unit 230 or in an execution parameter or a program of the comparison unit 235 or is stored in a storage unit (not shown in the figure) of the display panel 260 for being read and used by the voltage regulation unit 230.

In some embodiments of this application, the voltage regulation unit 230 takes a maximum one VCOM_R(max) out of the n standard feedback voltages VCOM_R to calculate the deviation value.

In some embodiments of this application, the voltage regulation unit 230 takes a minimum one VCOM_R(min) out of the n standard feedback voltages VCOM_R to calculate the deviation value.

In some embodiments, during a period of regulating, by the voltage regulation unit 230, the standard voltage VCOM, when the deviation value is less than the voltage threshold Vth, the voltage regulation unit 230 stops regulating the standard voltage VCOM.

In some embodiments, during the period of regulating, by the voltage regulation unit 230, the standard voltage VCOM, the voltage regulation unit 230 continuously receives the deviation values, and when the voltage regulation unit 230 receives a minimum deviation value from all the deviation values, and the minimum deviation value is less than the voltage threshold Vth, the voltage regulation unit 230 stops regulating the standard voltage VCOM.

In some embodiments, when the voltage regulation unit 230 regulates the standard voltage VCOM, the voltage regulation unit 230 uses the standard voltage VCOM as a start and positively or negatively regulates a voltage value range VCOM_add, that is, a range of VCOM+VCOM_add to VCOM−VCOM_add.

In some embodiments, the voltage value range VCOM_add is preset in an execution parameter or a program of the voltage regulation unit 230 or is stored in a storage unit (not shown in the figure) of the display panel 260 for being read and used by the voltage regulation unit 230.

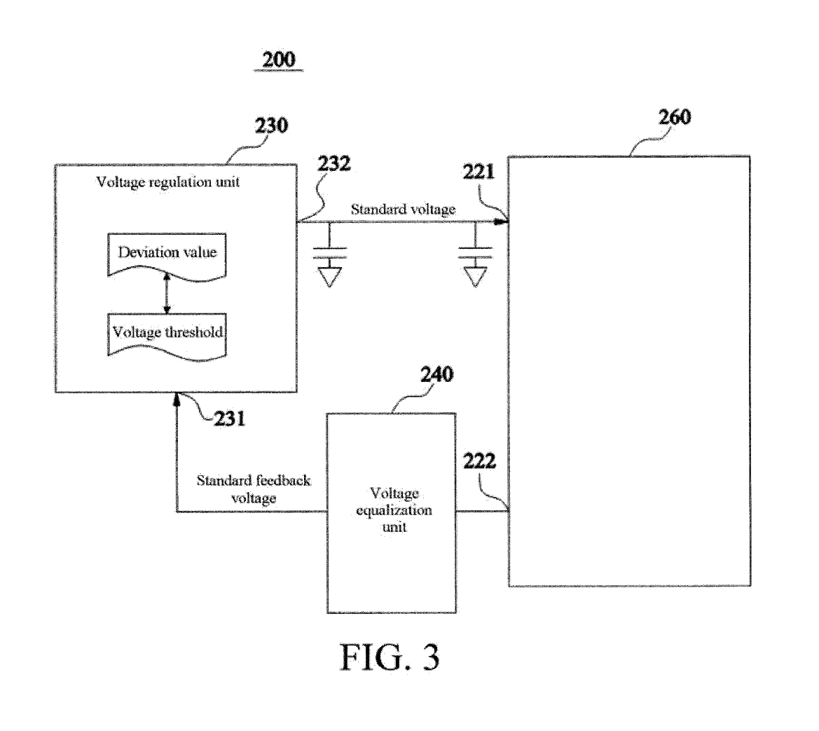

FIG. 3 is a schematic architectural diagram of an embodiment being applied to a driving circuit of a display apparatus according to a method of this application. In some embodiments, a voltage equalization unit 240 is disposed between the voltage regulation unit 230 and the display panel 260, the voltage equalization unit 240 continuously samples voltage signals on the second output line 222, and after sampling the voltage signals for a specific number of sampling times or continuously sampling the voltage signals in a specific time, the voltage equalization unit 240 provides an average of sample values as a standard feedback voltage VCOM_R.

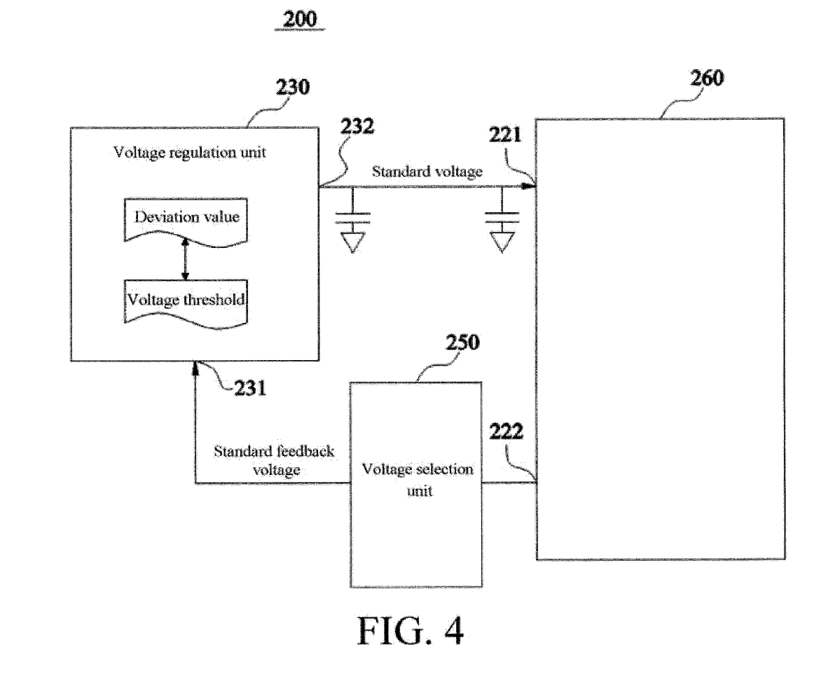

FIG. 4 is a schematic architectural diagram of a driving circuit for applying an embodiment to a display apparatus according to a method of this application. In some embodiments, a voltage selection unit 250 is disposed between the voltage regulation unit 230 and the display panel 260. The voltage selection unit 250 continuously samples voltage signals on the second output line 222, and after sampling the voltage signals for a specific number of sampling times or continuously sampling the voltage signals in a specific time, the voltage selection unit 250 provides more than one sample values out of all sample values as standard feedback voltages VCOM_R and feeds the standard feedback voltages VCOM_R back to the voltage regulation unit 230. Selection logic of the voltage selection unit 250 depends on actual requirements of a designer, and is not limited.

In some embodiments, the voltage regulation unit 230 is a DVR or a mechanical VR.

In some embodiments, when the voltage regulation unit 230 is a DVR, an analog/digital signal converter is disposed between the voltage regulation unit 230 and the display panel 260, so as to convert the standard feedback voltage VCOM_R into a digital signal.

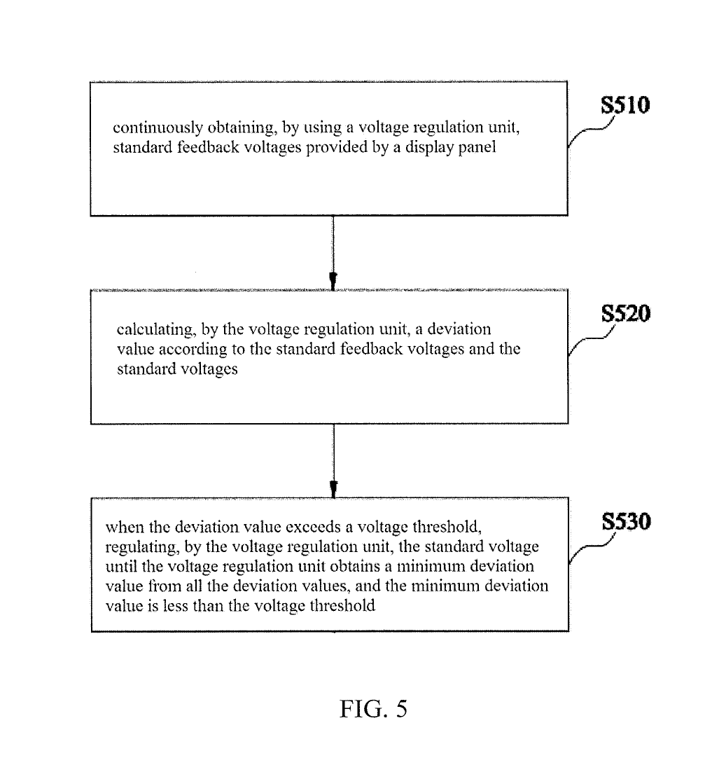

FIG. 5 is a schematic diagram of a driving process for applying an embodiment to a display apparatus according to a method of this application. In an embodiment of this application, a driving method of a display apparatus 200 of this application includes:

Step S510: Continuously receive, by using a voltage regulation unit 230, standard feedback voltages VCOM_R provided by a display panel 260.

Step S520: Calculate, by the voltage regulation unit 230, a deviation value according to the standard feedback voltages VCOM_R and the standard voltages VCOM.

S530: When the deviation value exceeds a voltage threshold Vth, regulate, by the voltage regulation unit 230, the standard voltage VCOM until the voltage regulation unit 230 receives a minimum deviation value from all the deviation values, and the minimum deviation value is less than the voltage threshold.

In an embodiment of this application, a display apparatus 200 of this application includes a voltage regulation unit 230, including a first output line 232 and a first input line 231, where the first output line 232 outputs a standard voltage VCOM, the first input line 231 inputs a standard feedback voltage VCOM_R, and the voltage regulation unit 230 stores a voltage threshold Vth; and a display panel 260, including a second input line 221 and a second output line 222, where the second input line 221 receives the standard voltage VCOM, and the second output line 222 outputs the standard feedback voltage VCOM_R; where: the voltage regulation unit 230 is configured to continuously receive the standard feedback voltages VCOM_R and to calculate a deviation value |VCOM_R−VCOM| according to the standard feedback voltages VCOM_R and the standard voltages VCOM; when the deviation value exceeds the voltage threshold Vth, the voltage regulation unit 230 uses the standard voltage VCOM as a start and positively or negatively regulates a voltage value range VCOM_add; during a period of regulating, by the voltage regulation unit 230, the standard voltage, the voltage regulation unit continuously receives the deviation values; and when the voltage regulation unit 230 receives a minimum deviation value out of all the deviation values, and when the minimum deviation value is less than the voltage threshold Vth, the voltage regulation unit 230 stops regulating the standard voltage VCOM.

This application can maintain original processing requirements and product costs on the premise of not greatly changing an existing production process, and after a display panel is used for a long time, a standard voltage VCOM can still be maintained at a proper voltage value, and be maintained in a proper value correspondence with a gamma reference voltage, thereby resolving problems of flickers and unstable brightness of the display panel caused by deviation of the standard voltage from an optimal value.

The wordings such as “in some embodiments” and “in various embodiments” are repeatedly used. The wordings usually refer to different embodiments, but they may also refer to a same embodiment. The words, such as “comprise”, “have”, and “include”, are synonyms, unless other meanings are indicated in the context thereof.

Descriptions above are merely preferred embodiments of this application, and are not intended to limit this application. Although this application has been disclosed above in forms of preferred embodiments, the embodiments are not intended to limit this application. A person skilled in the art can make some equivalent variations, alterations or modifications to the above disclosed technical content without departing from the scope of the technical solutions of the above disclosed technical content to receive equivalent embodiments. Any simple alteration, equivalent change or modification made to the foregoing embodiments according to the technical essence of this application without departing from the content of the technical solutions of this application shall fall within the scope of the technical solutions of this application.

What is claimed is:

1. A display apparatus, comprising:
a voltage regulation unit, comprising a first output line and a first input line, wherein the first output line is configured to output a standard voltage, and the first input line is configured to input a standard feedback voltage; and
a display panel, comprising a second input line and a second output line, wherein the second input line is configured to receive the standard voltage, and the second output line is configured to output the standard feedback voltage, wherein:
the voltage regulation unit is configured to receive the standard feedback voltage, and to calculate a regulation parameter according to a value of the standard feedback voltage, and to regulate the standard voltage according to the regulation parameter.

2. The display apparatus according to claim 1, wherein the voltage regulation unit stores a voltage threshold.

3. The display apparatus according to claim 2, wherein the regulation parameter is a deviation value between the standard feedback voltage and the standard voltage.

4. The display apparatus according to claim 3, wherein when the deviation value exceeds the voltage threshold, the voltage regulation unit regulates the standard voltage.

5. The display apparatus according to claim 4, wherein during a period of regulating, by the voltage regulation unit, the standard voltage, when the deviation value is less than the voltage threshold, the voltage regulation unit stops regulating the standard voltage.

6. The display apparatus according to claim 5, wherein during the period of regulating, by the voltage regulation unit, the standard voltage, when the deviation value is less than the voltage threshold, the voltage regulation unit stops regulating the standard voltage.

7. The display apparatus according to claim 3, wherein the voltage regulation unit continuously receives n standard feedback voltages within a time interval and takes one of the n standard feedback voltages to calculate the deviation value and n is a positive integer.

8. The display apparatus according to claim 7, wherein the voltage regulation unit takes a maximum one out of the n standard feedback voltages to calculate the deviation value.

9. The display apparatus according to claim 7, wherein the voltage regulation unit takes a minimum one out of the n standard feedback voltages to calculate the deviation value.

10. The display apparatus according to claim 1, wherein when the voltage regulation unit regulates the standard voltage, the voltage regulation unit uses the standard voltage as a start and positively regulates a voltage value range.

11. The display apparatus according to claim 1, wherein when the voltage regulation unit regulates the standard voltage, the voltage regulation unit uses the standard voltage as a start and negatively regulates a voltage value range.

12. A driving method of a display apparatus, comprising:
continuously receiving, by using a voltage regulation unit, standard feedback voltages provided by a display panel;
calculating, by the voltage regulation unit, a deviation value according to the standard feedback voltages and the standard voltages; and when the deviation value exceeds a voltage threshold, regulating, by the voltage regulation unit, the standard voltage until the voltage regulation unit receives a minimum deviation value from all the deviation values, and the minimum deviation value is less than the voltage threshold.

13. The driving method of a display apparatus according to claim 12, wherein the voltage regulation unit stores the voltage threshold.

14. The driving method of a display apparatus according to claim 12, wherein the voltage regulation unit continuously receives n standard feedback voltages within a time interval and takes one of the n standard feedback voltages to calculate the deviation value and n is a positive integer.

15. The driving method of a display apparatus according to claim 14, wherein the voltage regulation unit takes a maximum one out of the n standard feedback voltages to calculate the deviation value.

16. The driving method of a display apparatus according to claim 14, wherein the voltage regulation unit takes a minimum one out of the n standard feedback voltages to calculate the deviation value.

17. The driving method of a display apparatus according to claim 12, wherein the voltage regulation unit includes a comparison unit and the comparison unit performs a calculation on the deviation values and a value comparison between the deviation values and the voltage threshold.

18. The driving method of a display apparatus according to claim 12, wherein when the voltage regulation unit regulates the standard voltage, the voltage regulation unit uses the standard voltage as a start and positively regulates a voltage value range.

19. The display apparatus according to claim 12, wherein when the voltage regulation unit regulates the standard voltage, the voltage regulation unit uses the standard voltage as a start and negatively regulates a voltage value range.

20. A display apparatus, comprising:
a voltage regulation unit, comprising a first output line and a first input line, wherein the first output line outputs a standard voltage, the first input line inputs a standard feedback voltage, and the voltage regulation unit stores a voltage threshold; and
a display panel, comprising a second input line and a second output line, wherein the second input line receives the standard voltage, and the second output line outputs the standard feedback voltage, wherein:
the voltage regulation unit is configured to continuously receive the standard feedback voltages and to calculate a deviation value according to the standard feedback voltages and the standard voltages;
when the deviation value exceeds the voltage threshold, the voltage regulation unit uses the standard voltage as a start and positively or negatively regulates a voltage value range;
during a period of regulating, by the voltage regulation unit, the standard voltage, the voltage regulation unit continuously receives the deviation values;
the voltage regulation unit receives a minimum deviation value out of all the deviation values, and when the minimum deviation value is less than the voltage threshold, the voltage regulation unit stops regulating the standard voltage.
